(19) United States
(12) Patent Application Publication
(10) Pub. No.: US 2008/0131658 A1
(43) Pub. Date: Jun. 5, 2008

(54) Electronic packages and components thereof formed by co-deposited carbon nanotubes

(76) Inventors: Vijay Wakharkar, Paradise Valley, AZ (US); Nachiket Raravikar, Chandler, AZ (US)

Correspondence Address: TROP PRUNER & HU, PC, 1616 S. VOSS ROAD, SUITE 750, HOUSTON, TX, 77057-2631, US

(21) Appl. No.: 11/633,821

(22) Filed: Dec. 5, 2006

(51) Int. Cl. H01B 1/04; C25D 9/04; H05K 3/00

(52) U.S. Cl. 428/137; 205/50; 427/98.4; 428/195.1; 977/745

(57) ABSTRACT

Microelectronic packages may be formed using the co-deposition of carbon nanotubes. The carbon nanotubes may be functionalized to have an appropriate charge so they can be combined with other materials to give suitable properties. The other materials that are co-deposited may include metals, ceramics, and polymers. The electronic package components may be formed including thermal interface materials, vias, trenches, capacitors, memories, substrates, and substrate cores, as a few examples.

### BACKGROUND

This relates generally to electronic packages and, particularly, to packages for integrated circuit chips such as microprocessors.

Integrated circuit packages connect to contacts on an integrated circuit chip. The integrated circuit package, in turn, provides connections to the chip through the package. Because of the large number of inputs and outputs that may be involved and, in some cases, the high frequencies involved, there are numerous complexities in forming integrated circuit packages. Ideally, to obtain the greatest possible speed it is desirable to have relatively low resistance packaging. This means that a large number of connections can be made with relatively little resistance.

Conventional integrated circuit packages are made of conductors formed of metals. Generally, these metals are limited in terms of conductivity. Moreover, with existing metals, certain thermal dissipation may be achieved, but there are limits to those possible thermal dissipations inherent in the type of material. Likewise, the metal materials have a given strength for a size at which they are deposited, but, again, this size is relatively limited by the nature of the metals used.

### BRIEF DESCRIPTION OF THE DRAWINGS

FIG. 1 is an enlarged, cross-sectional view of an electronic package in accordance with one embodiment of the present invention;

FIG. 2 is a depiction of an electrolytic bath in accordance with one embodiment of the present invention; and

FIG. 3 is a system depiction.

### DETAILED DESCRIPTION

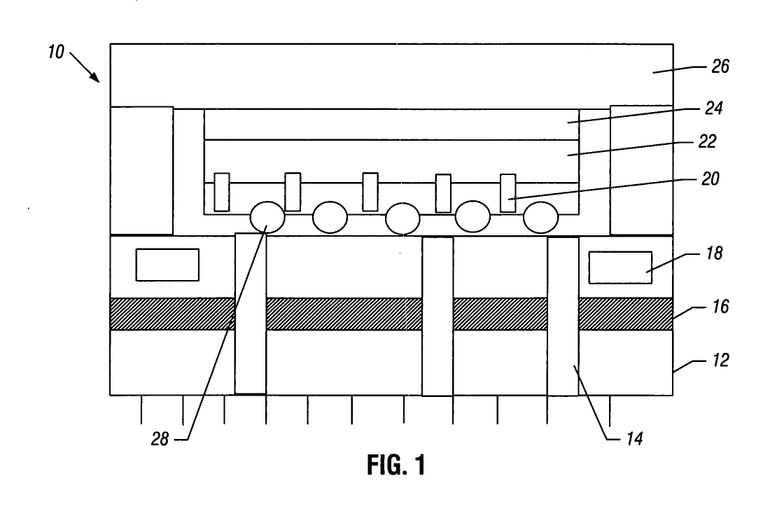

Referring to FIG. 1, an integrated circuit electronic package 10 may have superior properties by virtue of the use of co-deposited carbon nanotubes. That is, carbon nanotubes may be deposited to form various structures of the package 10. Carbon nanotubes may have, in given applications, superior properties to those achievable with conventional metals. For example, carbon nanotubes may have superior mechanical strength, superior conductivity, or superior thermal conductivity.

In order to achieve the desired results, the carbon nanotubes may be co-deposited with another material. The materials that may be co-deposited may include at least the following general types: metals, polymers, and ceramics.

As non-limiting examples, co-depositions of a metal with carbon nanotubes may be used to form thermal interface materials, silicon trenches, and vias for sensors and interconnect applications, first and second level package interconnects, substrate vias and trenches, interconnects, and memory cells. Co-deposition of polymers with carbon nanotubes may be used to make substrate cores with high strength carbon nanotube based epoxy composites, ultra-thin capacitors with carbon nanotube interconnect terminals, carbon nanotube polymer composites for high adhesion surfaces where the projecting carbon nanotubes act as mechanical entanglements, conducting polymer carbon nanotubes interconnects based on polyaniline and carbon nanotube components as bond/electrode pads for low end applications requiring ultra small interconnects. Composites of ceramics and carbon nanotubes may be used for magnetic nanoparticles with the carbon nanotubes offering conducting properties for magnetic memories and electromagnetic switches in microelectromechanical devices.

The nanotube electrodeposition may be done by electroplating, electroless plating, or electrophoresis, as examples. Selectivity of deposition of nanotubes and their composites may be achieved by masking unwanted areas of electrodes with Teflon or photoresist polymer such as polymethylmethacrylate (PMMA). Electrodeposition of nanotubes in the case of composites may be via electrodeposition owing to the charge on the nanotubes and adsorption of the nanotubes due to their high surface energy.

Electroless plating may be used where nanotubes need to be co-deposited with other materials. The co-deposited metals, such as nickel or copper, may be plated by electroless plating. The nanotubes are plated purely due to surface absorption along with the nickel. This process may have applications in second level thermal interface materials in semiconductor packages.

Electrophoresis may be utilized for selective deposition of nanotubes in silicon trenches, or microelectric substrate trenches. Electrophoresis works for deposition of pure nanotubes, as well as for co-depositions of nanotubes with metals, polymers, or ceramics. Particularly, copper and carbon nanotube composites may be formed, for example.

Vapor grown carbon nanotube nanofibers formed by a catalyst assisted chemical vapor deposition may be deposited by electroplating. The carbon nanofiber filler may have a diameter of 100 to 200 nanometers or lower, the fibers being about 20 microns long. A base plating bath of sulfuric acid may be used, together with polyacrylic acid, with mean molecular weights of 5000 and 25,000 to aid in dispersion of the fibers in the bath in one embodiment. Aeration under galvanic conditions may be used at temperatures of 25° C. Pure copper and stainless steel plates with exposed surface areas may be used as the substrates. A phosphorus containing copper plate may act as the anode.

Electrophoresis deposition may be done by mixing 60 weight percent of single walled carbon nanotubes in 200 milliliters concentrated nitric/sulfuric acid solution for a few minutes. The suspension may be refluxed with magnetic stirring at 100 to 120° C. for a few hours. The suspension may then be filtered and the wet powder cleaned with distilled water and dried at room temperature. The powder may then be mixed with distilled water during sonication. A surface charge may be applied to the particle by adding 10⁻⁶ to 10⁻² mole of Mg(NO₃)₂₆H₂O. Carbon nanotubes may be patterned onto metal cathodes with a negative bias of 10 to 50 volts DC applied to a patterned metal plate.

Continuing with FIG. 1, the package 10 may include a substrate 12 coupled to a substrate core 16. Thus, thermal vias 14 may extend through the substrate 12, including its core 16. Also formed on the substrate may be capacitors or dynamic random access memories 18.

Formed on the substrate may be an integrated heat spreader 26 which encloses an integrated circuit having solder balls 28 to couple it electrically and mechanically to the substrate 12. The integrated circuit may include vias 14 through the silicon known as through silicon vias (TSVS) 20. The integrated circuit may also include a silicon dynamic random access memory or integrated voltage regulator 22. The integrated circuit itself may, for example, be a microprocessor. A first thermal interface material 24 may couple the integrated circuit to an integrated heat spreader 26.

Various materials may be co-deposited with nanotubes. The nanotubes may either be pristine or functionalized with one or more functional groups. Thus, pristine nanotubes are not functionalized as used herein and functionalized carbon nanotubes are nanotubes reacted with another material which has either a positive or negative charge. As a result of the reaction with another material, the nanotubes become electrically charged and charged nanotubes are described herein as functionalized.

For example, nanotubes may be reacted with a carboxyl or OH group to form negatively charged functionalized carbon nanotubes. Carbon nanotubes may be reacted with an amine to form positively charged carbon nanotube groups. The carbon nanotubes may be deposited by themselves or with metals or ceramics or polymers. Useful polymers include polyaniline, epoxy, and polyimide. Ceramics may include silica. Metals may include solder, copper, and gold. Thus, the composite may include a functionalizing agent to provide a charge, together with a material to be deposited with the carbon nanotube or only the carbon nanotubes themselves.

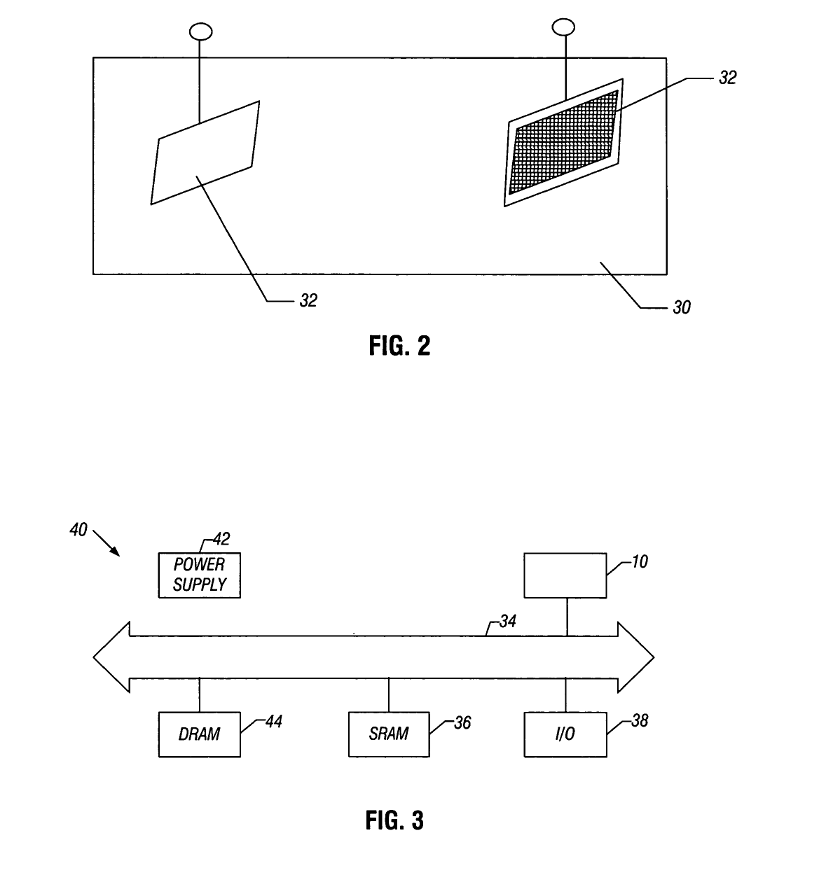

Pristine carbon nanotubes may be electroplated using an electrolytic bath as shown in FIG. 2. The electrolytic bath may include an electrolytic solution 30 with one or more solvents, such as sulfuric acid, copper sulfate, nitric acid, acetone, or toluene, to mention a few examples. Pristine or functionalized nanotubes are dispersed in these solvents with appropriate functionalizations. The nanotubes may be electrodeposited onto anode or cathode 32, depending on their functionalized charge. Although pristine nanotubes are known to be electron donors, the nanotube surface charge and polarity can be tailored by functionalization. The electrode surface may, for example, be pure silicon, Integrated Heat Spreader (IH-S), or organic or ceramic substrates, depending on the application.

Co-deposition of metal with carbon nanotubes may be achieved by dispersing the carbon nanotubes in electrolyte solution such as sulfuric acid. The carbon nanotubes may be functionalized with carboxyl or thiol groups which are suitable for bonding with metals and then dissolved in an acid bath. Metals such as solder or copper may also be dissolved directly into the same bath, for example, with sulfuric acid and then co-deposited along with the nanotubes. Suitable solders include indium or tin or tin silver alloys or tin silver copper alloys, to mention a few examples.

Carbon nanotubes or carbon nanotube metal functionalized structures may be co-deposited with metals in the electrolytic bath onto electrodes. The choice of electrode depends on the charge of the carbon nanotube functionalization. The electrodes may be Integrated Heat Spreader (IH-S), silicon, or any other conductive surface used for microelectronic packaging applications.

The co-deposition of a carbon nanotube with ceramic material may involve the use of silica, alumina, zirconia, or magnetic iron oxide, functionalized with ionic groups such as alkyl sulfonate and potassium, R(OCH₂CH₂)₇O(CH₂)₃SO₃⁻K⁺, where R is the alkyl chain C₁₃H₂₇ to C₁₅H₂₉. These particles may be directly dispersed into the electrolytic acid bath. Pristine or functionalized carbon nanotubes may be dispersed in that bath. The functionalized ceramic nanoparticles and carbon nanotubes may then be co-deposited onto an electrode, suitable for the particular packaging application.

Carbon nanotubes may be co-deposited with polymers, including both conducting and non-conducting polymers. Examples of conducting and non-conducting polymers include, but are not limited to, conducting polymers with polyaniline or poly-m-phenylene vinylene or polyethylene oxide. Non-conducting polymers may include epoxies or polyimides. Aniline monomer may be dissolved into a sulfuric acid bath to be co-deposited along with negatively charged carbon nanotubes on a suitable electrode. Epoxy or non-conducting polymers may be chemically bonded to water soluble functional groups or radicals, such as silanes, and then dissolved in the acid bath.

The non-conducting polymers can also be attached to nanotube surfaces via amine functionalization prior to the dispersion of the latter into electrolytic solvents. The amine functionalization may be by acid reflux, together with ammonium plasma of carbon nanotubes. The co-deposition of carbon nanotubes and epoxy or other non-conducting polymers can occur purely by statistical probability of nanotube adsorption onto the electrode surface owing to the high surface energy of nanotubes.

Thus, the substrate 12, shown in FIG. 1, may be formed of high strength carbon nanotube based epoxy composites. The thermal via 14 may be formed by a metal carbon nanotube composite. The capacitors or dynamic random access memories 18 may also be made by metal carbon nanotube co-deposition. The capacitors and memories 18 may also be made of carbon nanotube electrodes with magnetic ceramics or metals. The through silicon via 20 may be made of a carbon nanotube metal co-deposition such as a carbon nanotube/copper composite for high current density applications. The thermal interface material 24 may be made of carbon nanotubes and polymers or carbon nanotubes and metal composites. The substrate core 16 may be made of carbon nanotube polymer composites from mechanical stability including high structural strength, low coefficient of thermal expansion, and high stiffness.

In some embodiments, electro co-deposition of carbon nanotubes and nanotube composites may offer advantages in terms of scalability, structural stability, selectivity, and enhancement of properties such as thermal conductivity, coefficient of thermal expansion, or electrical conductivity owing to interface tailoring and dispersion. The processes may be implemented, in some embodiments, near room temperature and thereby are compatible with packaging applications. Also, an electro co-deposition process may enable the use of existing scalable infrastructure, such as electroplating baths used for high volume silicon processing, in some cases.

Suitable nanotubes may have low coefficients of thermal expansion, for example, about 10⁻⁶/K, high thermal conductivity, for example, 3000 W-mK or higher, high current carrying capacity (approximately 10⁹ A/cm²), and high surface area due to high aspect ratios greater than 1000. Due to such unique structure and property characteristics, nanotubes may have a range of applications in microelectronic packaging including thermal interface materials, interconnects, vias, substrate trenches, microchannel walls for enhanced fluid wicking, reversible adhesive structures for mobile thermal interface materials, high strength composites for substrates, and substrate cores.

Referring to FIG. 3, in accordance with some embodiments of the present invention, a computer system 40 may be formed using the package 10 shown in FIG. 1. Particularly, a packaged processor may be coupled by a bus 34 to various other components such as dynamic random access memory (DRAM) 44, input/output (I/O) devices 38, and static random access memory (SRAM) 36. A suitable power supply 42 may supply power to the processor 10 and the other components.

In some embodiments of the present invention, any processor-based system may be formed. Thus, the embodiment shown in FIG. 3 is merely an example. By improving the power delivery network performance, the performance of an integrated circuit at high frequencies may be improved. In some embodiments, this may be done at relatively low cost and with relatively low process complexity.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a microelectronic package using co-deposition of carbon nanotubes and another material.

2. The method of claim 1 including functionalizing said carbon nanotubes.

3. The method of claim 2 including co-depositing functionalized carbon nanotubes with a metal.

4. The method of claim 2 including co-depositing functionalized carbon nanotubes with a polymer.

5. The method of claim 2 including co-depositing functionalized carbon nanotubes with ceramic.

6. The method of claim 1 including co-depositing the carbon nanotubes in an electrolytic bath.

7. The method of claim 1 including using selective co-deposition of carbon nanotubes.

8. The method of claim 1 including co-depositing carbon nanotubes with a conductive material.

9. The method of claim 1 including co-depositing carbon nanotubes with a non-conductive material.

10. The method of claim 1 including co-depositing carbon nanotubes in a depression in a substrate.

11. A microelectronic package comprising:
an integrated circuit; and
a co-deposition of carbon nanotubes and another material.

12. The package of claim 11 including a substrate including said co-deposition of carbon nanotubes.

13. The package of claim 12 wherein said co-deposition includes a polymer.

14. The package of claim 11 wherein said co-deposition includes a thermal via.

15. The package of claim 14 wherein said co-deposition includes copper.

16. The package of claim 11 including a capacitor including said co-deposition.

17. The package of claim 11 including a through silicon via including said co-deposition.

18. The package of claim 11 including a thermal interface material including said co-deposition.

19. The package of claim 18 wherein said co-deposition includes a ceramic.

20. A system comprising:
a packaged processor, said processor comprising:
an integrated circuit; and
a co-deposition of carbon nanotubes and another material; and
a dynamic random access memory coupled to said processor.

21. The system of claim 20 wherein said co-deposition includes a metal.

22. The system of claim 20 wherein said co-deposition includes a ceramic.

23. The system of claim 20 wherein said co-deposition includes a polymer.

24. The system of claim 20 wherein said carbon nanotubes are functionalized.

25. The system of claim 20 wherein said carbon nanotubes are not functionalized.
